(19) United States
(12) Patent Application Publication
(10) Pub. No.: US 2025/0014888 A1
(43) Pub. Date: Jan. 9, 2025

(54) WAFER PROCESSING METHOD

(71) Applicant: DISCO CORPORATION, Tokyo (JP)

(72) Inventors: Akira MIZUTANI, Tokyo (JP); Yusuke OHTAKE, Tokyo (JP)

(21) Appl. No.: 18/742,173

(22) Filed: Jun. 13, 2024

(30) Foreign Application Priority Data
Jul. 4, 2023 (JP) 2023-109814

(51) Int. Cl. H01L 21/02

(52) U.S. Cl. CPC H01L 21/02021; H01L 21/02013

(57) ABSTRACT

A wafer processing method includes a modified layer forming step of forming a modified layer along a chamfered portion by applying a laser beam having a wavelength transmissible through a wafer with a condensing point of the laser beam positioned in an inner part of a boundary portion between an effective region and the chamfered portion, a chamfered portion removing step of scattering and removing the chamfered portion by a centrifugal force by holding the wafer on a spinner table and rotating the wafer at high speed after the modified layer forming step is performed, and a processing step of processing the wafer to thin the wafer to a desired thickness by grinding an undersurface of the wafer after the chamfered portion removing step is performed.

### BACKGROUND OF THE INVENTION

### Field of the Invention

The present invention relates to a wafer processing method for processing a wafer having an effective region formed on a top surface thereof and a chamfered portion at an outer circumference thereof, the chamfered portion surrounding the effective region.

### Description of the Related Art

A wafer having a device region on a top surface thereof, in which device region a plurality of devices such as integrated circuits (ICs) or large-scale integration (LSI) circuits are formed in such a manner as to be demarcated by a plurality of intersecting planned dividing lines, is thinned to a desired thickness by having an undersurface thereof ground. The wafer is thereafter divided into individual device chips by a cutting apparatus or a laser processing apparatus. The divided device chips are used in electric apparatuses such as mobile telephones or personal computers.

In addition, a chamfered portion is formed at the outer circumference of the wafer. When the undersurface of the wafer is ground and thinned, the chamfered portion becomes sharp like a knife edge, causing such a problem as an operator being injured or a crack developing from the outer circumference of the wafer and damaging the devices.

Accordingly, the present applicant has proposed a technology that, before the undersurface of the wafer is ground, forms a modified layer in a ring shape within the wafer by applying a laser beam having a wavelength transmissible through the wafer with the condensing point of the laser beam positioned inward of the chamfered portion, so that the chamfered portion is removed when grinding processing is performed (see Japanese Patent Laid-Open No. 2020-088187).

### SUMMARY OF THE INVENTION

According to the technology described in Japanese Patent Laid-Open No. 2020-088187, the chamfered portion is removed by an external force applied at the time of the grinding processing. However, the chamfered portion may slightly remain without being completely removed from the outer circumference of the wafer. Consequently, problems occur in that, for example, the remaining part falls off and becomes a contamination source in a subsequent step, or causes chipping of device chips when the wafer is divided into individual device chips.

It is accordingly an object of the present invention to completely remove a chamfered portion from the outer circumference of a wafer, and provide a wafer processing method that can solve such a problem as quality being decreased due to a remaining part falling off and becoming a contamination source in a subsequent step or causing chipping of device chips when the wafer is divided into individual device chips.

In accordance with an aspect of the present invention, there is provided a wafer processing method for processing a wafer having an effective region formed on a top surface of the wafer and a chamfered portion at an outer circumference of the wafer, the chamfered portion surrounding the effective region, the method including a modified layer forming step of forming a modified layer along the chamfered portion by applying a laser beam having a wavelength transmissible through the wafer with a condensing point of the laser beam positioned in an inner part of a boundary portion between the effective region and the chamfered portion, a chamfered portion removing step of scattering and removing the chamfered portion by a centrifugal force by holding the wafer on a spinner table and rotating the wafer at high speed after the modified layer forming step is performed, and a processing step of processing the wafer to thin the wafer to a desired thickness by grinding an undersurface of the wafer after the chamfered portion removing step is performed.

Preferably, the modified layer forming step includes a first step of forming such a relatively deep first modified layer that a crack reaches the top surface of the wafer, by applying the laser beam with the condensing point of the laser beam positioned in the inner part of the boundary portion between the effective region and the chamfered portion, and a second step of forming a relatively shallow second modified layer that is outwardly or inwardly adjacent to the first modified layer and that does not reach the top surface. The chamfered portion can be warped from the effective region to the undersurface side with the first modified layer as a starting point by performing the first and second steps. Preferably, in the second step, the second modified layer is formed at a position to be ground and removed in the processing step. Preferably, in the chamfered portion removing step, a rotational speed of the spinner table is 1000 to 3000 rpm.

The wafer processing method according to the present invention can completely remove the chamfered portion from an outer circumferential edge of the wafer before performing the processing step of processing the wafer to thin it to a desired thickness by grinding the undersurface of the wafer, and can thus solve such a problem as the quality of devices being decreased due to the chamfered portion remaining at the outer circumference of the wafer and falling off and becoming a contamination source in a subsequent step or causing chipping of device chips when the wafer is divided into individual device chips.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of a bonded wafer as a workpiece in the present embodiment;

FIG. 1B is a perspective view of a single body wafer as a workpiece in the present embodiment;

FIG. 2A is a perspective view illustrating a mode of placing the bonded wafer on a chuck table in a modified layer forming step;

FIG. 2B is a perspective view illustrating a mode of forming a modified layer in the modified layer forming step;

FIG. 3A is a schematic sectional view illustrating a form of a first modified layer as a half cut;

FIG. 3B is a schematic sectional view illustrating a form of a second modified layer adjacent to the first modified layer illustrated in FIG. 3A;

FIG. 3C is a schematic sectional view illustrating another form of the second modified layer;

FIG. 4A is a schematic sectional view illustrating a form of a first modified layer as a full cut;

FIG. 4B is a schematic sectional view illustrating a form of a second modified layer adjacent to the first modified layer illustrated in FIG. 4A;

FIG. 4C is a schematic sectional view illustrating another form of the second modified layer;

FIG. 5 is a plan view illustrating a state in which radial division-purpose modified layers are formed in a first wafer included in the bonded wafer illustrated in FIG. 1A;

FIG. 6 is a general perspective view of a chamfered portion removing apparatus including a spinner table;

FIG. 7A and FIG. 7B are side views illustrating a mode of performing a chamfered portion removing step with a part of the chamfered portion removing apparatus illustrated in FIG. 6 sectioned; and

FIG. 8 is a perspective view illustrating a mode of performing a processing step.

### DETAILED DESCRIPTION OF THE PREFERRED EMBODIMENT

An embodiment of a wafer processing method configured on the basis of the present invention will hereinafter be described in detail with reference to the accompanying drawings.

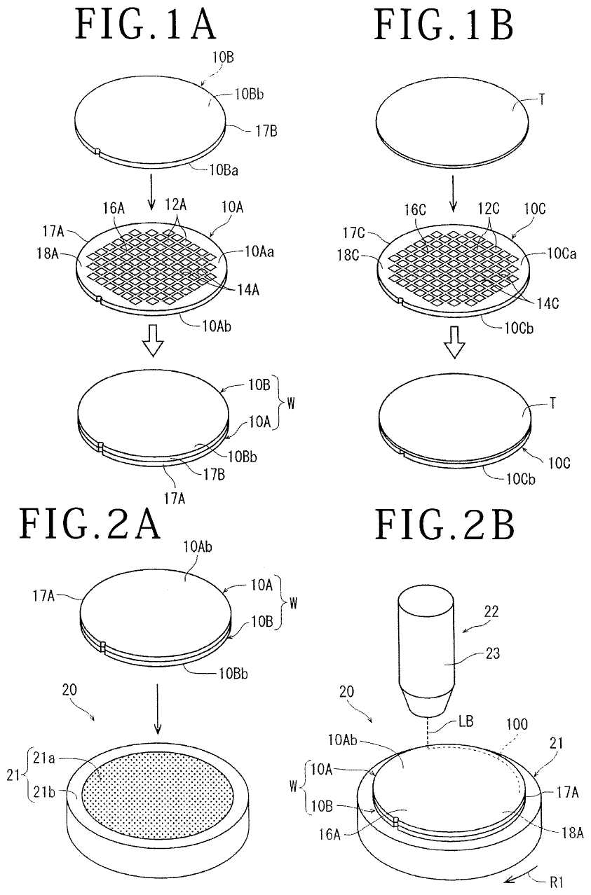

FIG. 1A illustrates a bonded wafer W to be processed by the wafer processing method configured on the basis of the present invention. The bonded wafer W is a bonded wafer in which a first wafer 10A and a second wafer 10B are bonded to each other to be integral with each other. The first wafer 10A is, for example, a silicon wafer having a diameter of 300 mm and a thickness of 300 μm. The first wafer 10A has a plurality of devices 12A formed on a top surface 10Aa thereof in such a manner as to be demarcated by a plurality of intersecting planned dividing lines 14A. The wafer 10A has the top surface 10Aa and an undersurface 10Ab and includes an effective region 16A on a central side where the devices 12A to be used as products are formed, a chamfered portion 17A formed at an end portion of an outer circumference surrounding the effective region 16A, and a boundary portion 18A between the effective region 16A and the chamfered portion 17A, in which boundary portion the devices 12A to be used as products are not formed. The second wafer 10B also has a configuration similar to that of the first wafer 10A. Though not illustrated, the second wafer 10B is a silicon wafer having a plurality of devices formed on a top surface 10Ba thereof directed downward in the figure in such a manner as to be demarcated by a plurality of intersecting planned dividing lines. The first wafer 10A and the second wafer 10B are, for example, made integral with each other through a siloxane bond by subjecting the top surface 10Aa of the first wafer 10A and the top surface 10Ba of the second wafer 10B to lamination and heat treatment.

FIG. 1B illustrates another wafer 10C to be processed by the wafer processing method according to the present embodiment. The wafer 10C is a single body wafer, and a protective tape T affixed to a top surface 10Ca of the wafer 10C is also illustrated. The wafer 10C illustrated in the figure, for example, has the same configuration as the above-described wafer 10A. The wafer 10C is a silicon wafer having a diameter of 300 mm and a thickness of 300 μm and has a plurality of devices 12C formed on the top surface 10Ca in such a manner as to be demarcated by a plurality of intersecting planned dividing lines 14C. The wafer 10C has the top surface 10Ca and an undersurface 10Cb and includes an effective region 16C on a central side where the devices 12C to be used as products are formed, a chamfered portion 17C formed at an end portion of an outer circumference surrounding the effective region 16C, and a boundary portion 18C between the effective region 16C and the chamfered portion 17C, in which boundary portion the devices 12C to be used as products are not formed. As described above, when the wafer 10C is to be processed by the wafer processing method according to the present embodiment, the protective tape T is affixed to the top surface 10Ca side to be made integral with the wafer 10C, as illustrated in the figure.

It is to be noted that the wafer to be processed by the wafer processing method according to the present invention is not limited to the above-described bonded wafer W formed by bonding two silicon wafers or the above-described single body silicon wafer 10C, and includes various wafers having an effective region and a chamfered portion at an end portion of an outer circumference surrounding the effective region. For example, the wafer may be a wafer of gallium nitride (GaN), a wafer of gallium arsenide (GaAs), a wafer of lithium tantalate (LiTaO₃), or a wafer of lithium niobate (LiNbO₃). Further, the wafer may be a wafer (for example, a glass wafer) that has no devices formed in a central region thereof but that has the central region to be subsequently processed and used as a product. In the embodiment to be described below, the wafer processing method according to the present embodiment will be described by taking the bonded wafer W described above as an example.

### (Modified Layer Forming Step)

At the time of performing the wafer processing method according to the present embodiment on the bonded wafer W, performed is a modified layer forming step which forms a modified layer along the chamfered portion 17A by positioning the condensing point of a laser beam having a wavelength transmissible through the first wafer 10A in an inner part of the boundary portion 18A between the effective region 16A and the chamfered portion 17A, and irradiating the inner part with the laser beam from the undersurface 10Ab of the first wafer 10A.

In the modified layer forming step, first, the bonded wafer W is transported to a laser processing apparatus 20 illustrated in FIG. 2A and FIG. 2B (only a part of the laser processing apparatus 20 is illustrated). The laser processing apparatus 20 includes at least a chuck table 21 illustrated in FIG. 2A and a laser beam irradiating unit 22 illustrated in FIG. 2B. The chuck table 21 includes a suction chuck 21a that forms a holding surface on an upper surface side and that is formed by a member having air permeability, and a frame body 21b surrounding the suction chuck 21a. The laser beam irradiating unit 22 includes a laser oscillator (not illustrated) that emits a laser beam having a wavelength transmissible through the first wafer 10A constituting the bonded wafer W, and a condenser 23 that condenses and applies the laser beam LB emitted by the laser oscillator. Further, the laser processing apparatus 20 includes a moving mechanism that moves the chuck table 21, a rotational driving mechanism that rotates the chuck table 21, suction means for generating a negative pressure on the upper surface of the suction chuck 21a, and the like (none of them is illustrated).

After the bonded wafer W is transported to the laser processing apparatus 20, as illustrated in FIG. 2A, the bonded wafer W is placed on the chuck table 21 with an undersurface 10Bb side of the second wafer 10B directed downward and with the undersurface 10Ab side of the first wafer 10A directed upward, and the suction means not illustrated in the figure is actuated to hold the bonded wafer W under suction. The bonded wafer W held under suction on the chuck table 21 is subjected to alignment using an alignment unit and a height detector (neither of them is illustrated) arranged in the laser processing apparatus 20. The position of the outer circumferential end portion at which the chamfered portion 17A of the first wafer 10A is formed and the central position of the first wafer 10A are detected, and besides, the upper surface height of the undersurface 10Ab of the first wafer 10A is detected. Further, a processing position to be irradiated with the laser beam LB in the boundary portion 18A described above is detected.

The modified layer forming step performed in the present invention can be performed including, for example, a first step and a second step to be described below.

### (First Step)

When the position of the end portion of the outer circumference at which the chamfered portion 17A of the first wafer 10A is formed and the central position of the first wafer 10A are detected, for example, a position inward of a region where the chamfered portion 17A is formed from the end portion of the outer circumference of the first wafer 10A (for example, a region of 0.5 mm from the end portion of the outer circumference), that is, a position of a radius of 147 mm, for example, from the center point of the first wafer 10A which position is set annularly to correspond to the boundary portion 18A described above, is detected as a predetermined processing position to be subjected to laser processing in the first step to form a modified layer. The positional information regarding the processing position thus detected is stored in a controller not illustrated in the figures.

On the basis of the information regarding the processing position detected in the first step by the alignment described above, the chuck table 21 is moved to position the predetermined processing position described above directly below the condenser 23 of the laser beam irradiating unit 22, as illustrated in FIG. 2B. Next, a first modified layer 100 is formed over the entire circumference along the chamfered portion 17A of the first wafer 10A by positioning the condensing point of the laser beam LB at an inner part of the boundary portion 18A and irradiating the inner part with the laser beam LB from the undersurface 10Ab side of the first wafer 10A, and at the same time, rotating the chuck table 21 in a direction indicated by an arrow R1.

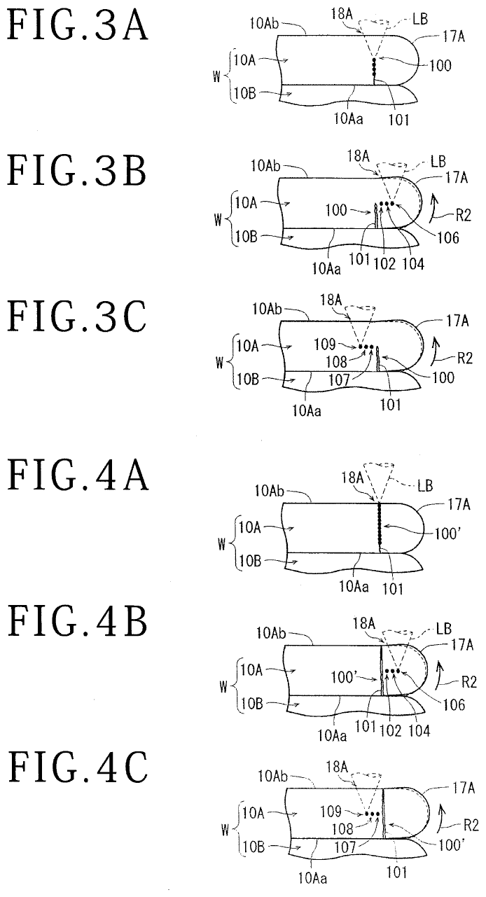

As illustrated in FIG. 3A, the first modified layer 100 formed by the first step described above is formed at such a relatively deep position that a crack 101 occurs as a result of the formation of the first modified layer 100 and the crack 101 reaches the top surface 10Aa side of the first wafer 10A. Further, this first modified layer 100 is preferably formed by a plurality of layers in an upward-downward direction. For example, the first modified layer 100 illustrated in FIG. 3A is constituted by four modified layers in the upward-downward direction. At the time of forming such a first modified layer 100, first, the laser beam LB is applied with the condensing point of the laser beam LB positioned at a position set at a deepest portion within the boundary portion 18A of the first wafer 10A (for example, at a depth of 180 μm from the undersurface 10Ab), and at the same time, the chuck table 21 is rotated as described above. A first annular modified layer is thus formed along the chamfered portion 17A. Thereafter, while the chuck table 21 is rotated, the condensing point is raised three times toward the undersurface 10Ab side (upward) such that the depth from the undersurface 10Ab becomes a depth of 170 μm→160 μm→150 μm, for example. A total of four annular modified layers are thus formed along the chamfered portion 17A. In addition, the crack 101 reaching the top surface 10Aa side of the first wafer 10A is produced. Incidentally, the first modified layer 100 and the crack 101 formed by the first step described above do not extend from the top surface 10Aa to the undersurface 10Ab of the first wafer 10A. Therefore, the first modified layer 100 illustrated in FIGS. 3A to 3C will hereinafter be referred to also as a half cut. As a result of the above, the first step is completed.

### (Second Step)

After the first modified layer 100 is formed by the first step as described above, performed is the second step which forms a relatively shallow second modified layer that does not reach the top surface 10Aa of the first wafer 10A, outward or inward of the first modified layer 100. More specifically, as illustrated in FIG. 3B, for example, the laser beam LB is applied with the condensing point of the laser beam LB positioned at a position outwardly adjacent to the uppermost modified layer (at the depth of 150 μm from the undersurface 10Ab) in the first modified layer 100, and the chuck table 21 is rotated. An annular modified layer 102 is thus formed. The second modified layer formed by the second step is preferably formed by a plurality of modified layers, as illustrated in FIG. 3B. In the present embodiment, the laser beam LB is applied with the condensing point of the laser beam LB positioned at a depth same as that of the modified layer 102 so as to be outwardly adjacent to the annular modified layer 102. Annular modified layers 104 and 106 are thus formed in addition to the annular modified layer 102 described above. As a result of the above, the second step is completed, and the modified layer forming step is completed.

The first modified layer 100 is formed by performing the first step described above, thereby forming the crack 101 reaching the top surface 10Aa side of the first wafer 10A. Further, the second modified layers 102, 104, and 106 are formed as described above by performing the second step. This causes a stress to be applied to the first modified layer 100. Thus, as illustrated in FIG. 3B, the crack 101 further extends in the upward-downward direction along the first modified layer 100, and with the first modified layer 100 as a starting point, the chamfered portion 17A can be warped over the entire circumference in a direction indicated by an arrow R2 in the figure, that is, to the undersurface 10Ab side. It is to be noted that the formation of the second modified layer is not limited to the formation of the annular modified layers by positioning the condensing point at three positions as described above, and annular modified layers may be formed by positioning the condensing point at two positions or less or four positions or more. Preferably, annular modified layers are formed by positioning the condensing point at three to six positions to perform irradiation.

Laser processing conditions at the time of performing the modified layer forming step including the first step and the second step described above are set as follows, for example.
Wavelength: 1099 nm
Repetition frequency: 80 kHz
Average power: 2.0 W
Processing feed speed: 450 mm/s
or
Wavelength: 1342 nm
Repetition frequency: 90 kHz
Average power: 1.9 W
Processing feed speed: 400 mm/s

The position of the second modified layer formed by the second step performed in the modified layer forming step according to the present invention is not limited to the mode illustrated in FIG. 3B. For example, as illustrated in FIG. 3C, the second modified layer (modified layers 107, 108, and 109) may be formed by applying the laser beam LB with the condensing point of the laser beam LB positioned at a position that is adjacent to the first modified layer 100 described above and that is a relatively shallow position not reaching the top surface 10Aa of the first wafer 10A inward (on the effective region side) of the inner part in the boundary portion 18A. The second modified layer illustrated in FIG. 3C (modified layers 107, 108, and 109) is also formed under laser processing conditions similar to those for the second modified layer illustrated in FIG. 3B (modified layers 102, 104, and 106). A stress can thus be applied to the first modified layer 100. The crack 101 is caused to extend in the upward-downward direction along the first modified layer 100, and with the first modified layer 100 as a starting point, the chamfered portion 17A can be warped in a direction indicated by an arrow R2 in the figure, that is, to the undersurface 10Ab side. The second modified layer (modified layers 107, 108, and 109) in this mode is set at such a depth position as to be removed when the first wafer 10A is processed to be thinned to a desired thickness by being ground at the undersurface 10Ab thereof in a subsequent processing step.

The modified layers formed in the modified layer forming step according to the present invention are not limited to the mode described above. FIG. 4A illustrates a first modified layer 100′ formed according to an embodiment different from the first step of the modified layer forming step described with reference to FIG. 3A. In the first step illustrated in FIG. 4A, the laser beam LB is applied with the condensing point of the laser beam LB positioned in an inner part of the boundary portion 18A between the effective region 16A and the chamfered portion 17A. The first modified layer 100′ is thus formed such that a crack 101 reaches the top surface 10Aa of the first wafer 10A and reaches the undersurface 10Ab thereof. At the time of forming such a first modified layer 100′, for example, first, the laser beam LB is applied with the condensing point of the laser beam LB positioned at a position set at a deepest portion within the boundary portion 18A of the first wafer 10A (for example, at a depth of 175 μm from the undersurface 10Ab), and at the same time, the chuck table 21 is rotated in the direction of R1 illustrated in FIG. 2B. A first annular modified layer is thus formed along the chamfered portion 17A. Thereafter, while the chuck table 21 is rotated, the condensing point is raised multiple times toward the undersurface 10Ab side (upward) such that the depth from the undersurface 10Ab becomes a depth of 165 μm→155 μm→135 μm→120 μm→105 μm→90 μm→70 μm→50 μm→35 μm→20 μm, for example. A total of 11 annular modified layers are thus formed along the chamfered portion 17A. As a result of the above, the first step is completed. Incidentally, the first modified layer 100′ and the crack 101 formed by the first step described with reference to FIG. 4A are formed in the whole of a region extending from the top surface 10Aa to the undersurface 10Ab of the first wafer 10A, and will therefore be referred to as a full cut, whereas the first modified layer 100 illustrated in FIG. 3A is referred to as a half cut.

The second step is performed after the first step described above is performed. The second step in this case can be performed by a procedure similar to that of the second step described with reference to FIG. 3B and FIG. 3C. Specifically, a relatively shallow second modified layer that does not reach the top surface 10Aa of the first wafer 10A is formed outward or inward of the first modified layer 100′. For example, as illustrated in FIG. 4B, the laser beam LB is applied with the condensing point of the laser beam LB positioned at a position outwardly adjacent to the modified layer formed at the depth of 150 μm from the undersurface 10Ab in the first modified layer 100′, and the chuck table 21 is rotated. An annular modified layer 102 is thus formed. Also in the present embodiment, as illustrated in FIG. 4B, the second modified layer formed by the second step is preferably formed by a plurality of modified layers. In the present embodiment, annular modified layers 104 and 106 are formed in addition to the annular modified layer 102 described above by applying the laser beam LB with the condensing point of the laser beam LB positioned at positions outwardly adjacent to the annular modified layer 102. As a result of the above, the second step is completed, and the modified layer forming step is completed.

The first modified layer 100′ is formed by performing the first step described above, and further, the second modified layers 102, 104, and 106 are formed as described above by performing the second step. This causes a stress to be applied to the first modified layer 100′. Thus, as in the embodiment described earlier, with the first modified layer 100′ as a starting point, the chamfered portion 17A can be warped in a direction indicated by an arrow R2 in FIG. 4B, that is, to the undersurface 10Ab side.

As the second modified layer formed by the second step in the modified layer forming step, as illustrated in FIG. 4C, the second modified layer (modified layers 107, 108, and 109) may be formed by applying the laser beam LB with the condensing point of the laser beam LB positioned at a position that is adjacent to the first modified layer 100′ described above and that is a shallow position not reaching the top surface 10Aa of the wafer 10A inward (on the effective region side) of the inner part in the boundary portion 18A. The second modified layer (modified layers 107, 108, and 109) illustrated in FIG. 4C can be formed by the procedure described with reference to FIG. 3C. As in the case of the second modified layer (modified layers 102, 104, and 106) illustrated in FIG. 4B, a stress can be applied to the first modified layer 100′. Thus, with the first modified layer 100′ as a starting point, the chamfered portion 17A can be warped in a direction indicated by an arrow R2 in the figure, that is, to the undersurface 10Ab side. The second modified layer (modified layers 107, 108, and 109) in this mode is also set at such a depth position as to be removed when the wafer 10A is processed to be thinned to a desired thickness by being ground at the undersurface 10Ab thereof in a subsequent processing step.

Laser processing conditions at the time of performing the modified layer forming step described with reference to FIGS. 4A to 4C are set as follows, for example. Incidentally, DF is a defocus position of the condensing point of the laser beam LB and denotes a depth position from the undersurface 10Ab of the first wafer 10A.
Wavelength: 1099 nm
Repetition frequency: 80 KHz
Average power: 2 W in a case where DF (μm) ≥135
   1 W in a case where DF (μm)<135
Processing feed speed: 450 mm/s
or
Wavelength: 1342 nm
Repetition frequency: 90 kHz
Average power: 1.9 W in a case where DF (μm) ≥135
   1 W in a case where DF (μm)<135
Processing feed speed: 400 mm/s

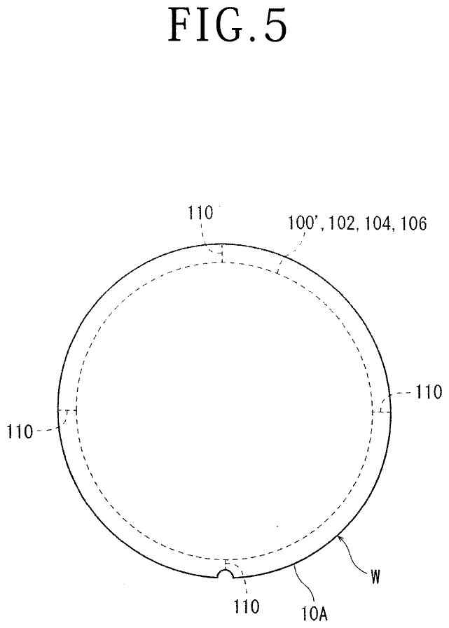

In addition to the first modified layer and the second modified layer formed by the modified layer forming step, as illustrated in FIG. 5, for example, radial division-purpose modified layers 110 may be formed to extend from the first modified layer 100′ in the direction toward an outer circumferential edge at which the chamfered portion 17A is formed. The division-purpose modified layers 110 illustrated in the figure are modified layers to be used for more finely dividing the chamfered portion 17A. The division-purpose modified layers 110 are formed by application of the laser beam LB under laser processing conditions similar to those for the first modified layers 100 and 100′ described above, for example, and are formed at a plurality of positions (four positions in the embodiment illustrated in the figure) at equal intervals along the chamfered portion 17A of the first wafer 10A. Because the division-purpose modified layers 110 are formed, the chamfered portion 17A is divided finely, and the removal of the chamfered portion 17A is performed excellently, when the chamfered portion 17A is removed in a chamfered portion removing step to be described later.

Also in a case where the modified layer forming step based on the present invention is performed on the single body silicon wafer 10C described with reference to FIG. 1B, the first modified layer 100 or 100′ and the second modified layer (the modified layers 102, 104, and 106 or the modified layers 107, 108, and 109) described with reference to FIGS. 3A to 4C can be formed by performing the first step and the second step described above. A procedure in the case of performing the modified layer forming step on the wafer 10C is the same as the procedure of forming the modified layers in the bonded wafer W described above except that the undersurface 10Cb of the wafer 10C is directed upward and that the protective tape T side is held under suction on the chuck table 21 of the laser processing apparatus 20. Detailed description of the procedure in the case of performing the modified layer forming step on the wafer 10C will therefore be omitted. The following description will be continued supposing that the modified layer forming step described above has formed the first modified layer 100 and the second modified layer (modified layers 102, 104, and 106) in the first wafer 10A of the bonded wafer W.

### (Chamfered Portion Removing Step)

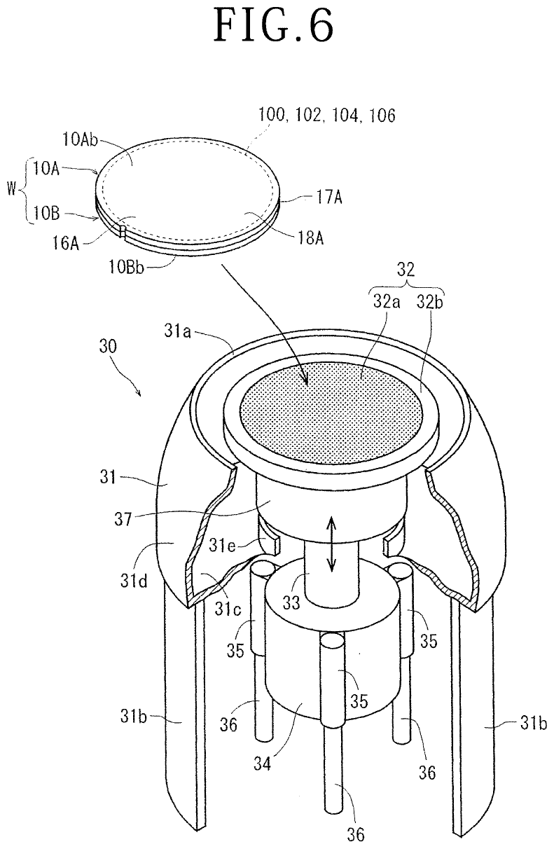

After the modified layer forming step is performed as described above, performed is a chamfered portion removing step which scatters and removes the chamfered portion 17A by a centrifugal force by rotating the bonded wafer W at high speed. FIG. 6 illustrates a chamfered portion removing apparatus 30 suitable for performing the chamfered portion removing step according to the present invention.

As illustrated in FIG. 6, the chamfered portion removing apparatus 30 includes a spinner table 32 and a cover unit 31 that surrounds the whole of the side of the spinner table 32 and that has a circular opening portion 31a in an upper part. Incidentally, in FIG. 6, for the convenience of description, a near side of the cover unit 31 is illustrated in a partially cutaway state. The spinner table 32 includes a suction chuck 32a formed by a porous member having air permeability and a frame portion 32b surrounding the suction chuck 32a. The suction chuck 32a is connected to suction means not illustrated in the figure and is thus capable of generating a suction force on the upper surface of the suction chuck 32a. A rotary shaft 33 is connected to the spinner table 32. The rotary shaft 33 is driven by a motor 34 to rotationally drive the spinner table 32. A plurality of air pistons 35 are arranged on the periphery of the motor 34. The spinner table 32, the rotary shaft 33, and the motor 34 can be raised or lowered integrally by rods 36 being caused to advance or retreat in the upward-downward direction by the air pistons 35. The rotary shaft 33 and the motor 34 described above function as a base that supports the spinner table 32.

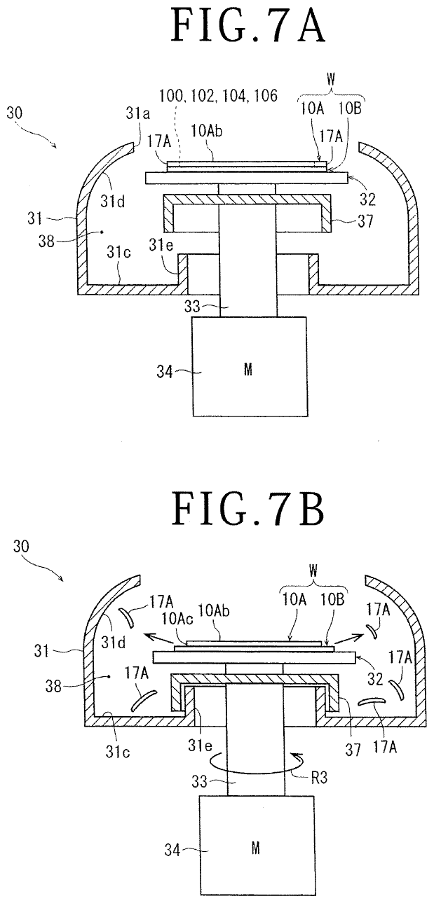

As is understood from FIG. 6, the cover unit 31 includes an annular bottom wall 31c, an outer wall 31d erected on an outer circumference of the bottom wall 31c, and an inner wall 31e erected on an inner circumference of the bottom wall 31c, and further includes a plurality of leg portions 31b that support the cover unit 31. The outer wall 31d forms a curved shape that is gradually reduced in diameter toward an upper side. The circular opening portion 31a is formed in a size slightly larger than the external shape size of the frame portion 32b of the spinner table 32. A skirt portion 37 that is provided to the rotary shaft 33 and that rotates together with the rotary shaft 33 is disposed on the lower side of the spinner table 32. The chamfered portion removing apparatus 30 roughly has the configuration as described above. A procedure of performing the chamfered portion removing step by using the chamfered portion removing apparatus 30 will be described below with reference also to FIG. 7A and FIG. 7B in addition to FIG. 6. Incidentally, in FIG. 7A and FIG. 7B, for the convenience of description, the outer wall 31d of the cover unit 31 and the skirt portion 37 described above are illustrated in section, and the leg portions 31b of the cover unit 31 and the air pistons 35 are not depicted.

At the time of performing the chamfered portion removing step, as illustrated in FIG. 7A, the air pistons 35 described above are actuated to raise the spinner table 32 within an internal space 38 of the cover unit 31 and to position the spinner table 32 in the vicinity of the opening portion 31a of the cover unit 31 as a loading/unloading position for loading the bonded wafer W. Then, the bonded wafer W resulting from the modified layer forming step is placed on the spinner table 32 with the first wafer 10A of the bonded wafer W directed upward and with the second wafer 10B side of the bonded wafer W directed downward. The suction means not illustrated in the figure is actuated to hold the bonded wafer W under suction on the spinner table 32.

When the bonded wafer W is held under suction on the spinner table 32, the air pistons 35 are actuated to lower the spinner table 32 and position the spinner table 32 at a chamfered portion removing position illustrated in FIG. 7B. At this time, the skirt portion 37 is placed into a state covering the outside of the inner wall 31e of the cover unit 31.

Next, the motor 34 is actuated to rotate the rotary shaft 33 for rotating the spinner table 32, at high speed in a direction indicated by an arrow R3 in FIG. 7B for a predetermined period of time. The rotational speed of the rotary shaft 33 is preferably 1000 to 3000 rpm, for example. When the spinner table 32 is thus rotated at high speed, a strong centrifugal force acts on the chamfered portion 17A. Consequently, the chamfered portion 17A is separated starting at the first modified layer 100 or the first modified layer 100′ formed by the modified layer forming step described above and is scattered from an outer circumferential edge 10Ac of the first wafer 10A into the internal space 38 of the cover unit 31. The chamfered portion 17A is thus removed from the first wafer 10A. The chamfered portion removing step is then completed. At this time, because the outer wall 31d of the cover unit 31 is formed in such a manner as to be reduced in diameter toward the upper side as described above, the scattered pieces of the chamfered portion 17A fall along an inner surface of the outer wall 31d of the cover unit 31, and the scattering of the chamfered portion 17A to the outside of the cover unit 31 is suppressed. The pieces of the chamfered portion 17A removed from the first wafer 10A are accumulated on the bottom wall 31c of the cover unit 31 and are therefore collected periodically after the chamfered portion removing step is performed on a plurality of bonded wafers W.

After the chamfered portion removing step described above is completed, performed is a processing step which processes the bonded wafer W to thin it to a desired thickness by grinding the undersurface 10Ab of the first wafer 10A of the bonded wafer W. The following description will be made of a mode of performing the processing step that processes the bonded wafer W including the first wafer 10A, from which the chamfered portion 17A has been removed by the chamfered portion removing step described above, to thin the bonded wafer W to a desired thickness by grinding the undersurface 10Ab of the bonded wafer W.

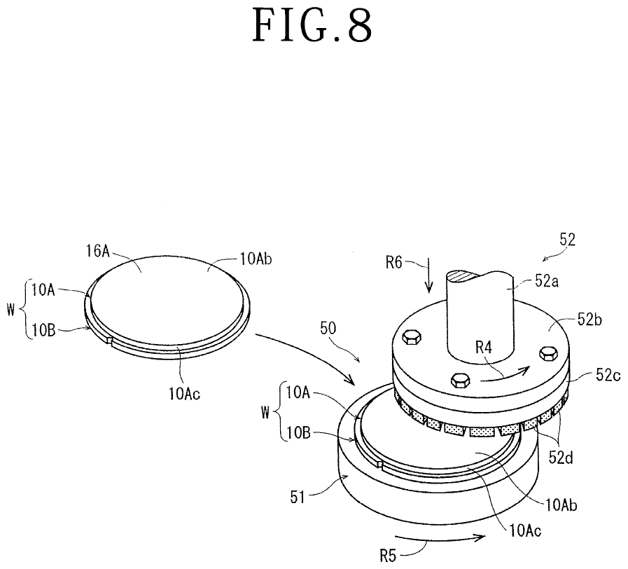

The bonded wafer W resulting from the chamfered portion removing step is transported to a grinding apparatus 50 illustrated on the right side of FIG. 8 (only a part of the grinding apparatus 50 is illustrated). As illustrated in the figure, the grinding apparatus 50 includes a grinding unit 52 for grinding and thinning a workpiece held under suction on a chuck table 51. The grinding unit 52 includes a rotary spindle 52a to be rotated by a rotational driving mechanism not illustrated in the figure, a wheel mount 52b fitted to a lower end of the rotary spindle 52a, and a grinding wheel 52c attached to a lower surface of the wheel mount 52b. A plurality of grinding stones 52d are annularly provided to a lower surface of the grinding wheel 52c.

As illustrated in the figure, the bonded wafer W is transported to the grinding apparatus 50, is placed onto the chuck table 51 with the second wafer 10B side directed downward, and is held under suction by suction means not illustrated in the figure being actuated. Next, while the rotary spindle 52a of the grinding unit 52 is rotated in a direction indicated by an arrow R4 in FIG. 8 at 6000 rpm, for example, the chuck table 51 is rotated in a direction indicated by an arrow R5 at 300 rpm, for example. Then, while grinding water supply means not illustrated in the figure supplies grinding water onto the undersurface 10Ab of the first wafer 10A, the grinding stones 52d are brought into contact with the undersurface 10Ab of the first wafer 10A, and the grinding wheel 52c is grinding-fed in a downward direction indicated by an arrow R6 at a grinding feed speed of 1.0 μm/s, for example. At this time, grinding can be made to progress while the thickness of the bonded wafer W is measured by a contact type or noncontact type measuring gauge not illustrated in the figure. After the bonded wafer W is reduced to a desired thickness through grinding of the undersurface 10Ab of the first wafer 10A by a predetermined amount, the grinding unit 52 is stopped and retracted. The processing step is then completed. Incidentally, after the processing step is completed, a cleaning step, a drying step, and the like, details of which will be omitted, are performed as appropriate. While illustrated is the mode in which the above-described processing step processes the bonded wafer W formed by bonding the first wafer 10A and the second wafer 10B to each other, to thin the bonded wafer W to a desired thickness by grinding the undersurface 10Ab of the first wafer 10A in the bonded wafer W, the grinding apparatus 50 described above can perform processing by a similar procedure also in a case where the single body wafer 10C is processed to be thinned to a desired thickness by being ground at the undersurface 10Cb of the wafer 10C resulting from the modified layer forming step and the chamfered portion removing step. As a result of the above, the wafer processing method according to the present embodiment is completed.

The processing method according to the foregoing embodiment can completely remove the chamfered portion from the outer circumferential edge of the wafer before performing the processing step of processing the wafer to thin it to a desired thickness by grinding the undersurface of the wafer, and hence, solves such a problem as the quality of devices being decreased due to the chamfered portion remaining at the outer circumference of the wafer and falling off and becoming a contamination source in a subsequent step or causing chipping of device chips when the wafer is divided into individual device chips.

It is to be noted that the modified layers formed by the modified layer forming step in the present invention are not limited to the modified layers formed by the first step and the second step described above. For example, the second step may be omitted, and only the first step may be performed to form only the first modified layer 100 as a half cut or the first modified layer 100′ as a full cut. In addition, the radial division-purpose modified layers 110 described above may be combined as appropriate after the first modified layer 100 or the first modified layer 100′ described above is formed by performing only the first step.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer processing method for processing a wafer having an effective region formed on a top surface of the wafer and a chamfered portion at an outer circumference of the wafer, the chamfered portion surrounding the effective region, the method comprising:
a modified layer forming step of forming a modified layer along the chamfered portion by applying a laser beam having a wavelength transmissible through the wafer with a condensing point of the laser beam positioned in an inner part of a boundary portion between the effective region and the chamfered portion;
a chamfered portion removing step of scattering and removing the chamfered portion by a centrifugal force by holding the wafer on a spinner table and rotating the wafer at high speed after the modified layer forming step is performed; and
a processing step of processing the wafer to thin the wafer to a desired thickness by grinding an undersurface of the wafer after the chamfered portion removing step is performed.

2. The wafer processing method according to claim 1, wherein
the modified layer forming step includes
a first step of forming such a relatively deep first modified layer that a crack reaches the top surface of the wafer, by applying the laser beam with the condensing point of the laser beam positioned in the inner part of the boundary portion between the effective region and the chamfered portion, and
a second step of forming a relatively shallow second modified layer that is outwardly or inwardly adjacent to the first modified layer and that does not reach the top surface, and
the chamfered portion is warped from the effective region to the undersurface side with the first modified layer as a starting point.

3. The wafer processing method according to claim 1, wherein
the wafer is a bonded wafer formed by bonding a first wafer and a second wafer to each other, and
the modified layer forming step, the chamfered portion removing step, and the processing step are performed on the first wafer.

4. The wafer processing method according to claim 2, wherein,
in the second step, the second modified layer is formed at a position to be ground and removed in the processing step.

5. The wafer processing method according to claim 1, wherein,
in the chamfered portion removing step, a rotational speed of the spinner table is 1000 to 3000 rpm.
